(19) United States
(12) Patent Application Publication
(10) Pub. No.: US 2025/0327841 A1
(43) Pub. Date: Oct. 23, 2025

(54) COATED ACTIVE COMPONENT IN A HIGH-VOLTAGE DEVICE AND METHOD FOR INCREASING THE DI-ELECTRIC STRENGTH

(71) Applicant: HSP Hochspannungsgeräte GmbH, Troisdorf (DE)

(72) Inventors: Udo Prucker, Schwaig (DE); Sebastian Baehr, Eggolsheim (DE)

(21) Appl. No.: 18/871,052

(22) PCT Filed: May 26, 2023
(86) PCT No.: PCT/EP2023/064160

§ 371 Date: Dec. 2, 2024

(30) Foreign Application Priority Data
Jun. 3, 2022 (DE) 10 2022 205 691.4

(51) Int. Cl. G01R 19/00; G01D 11/24

(52) U.S. Cl. CPC G01R 19/0046; G01D 11/245

(57) ABSTRACT

The invention relates to a high-voltage device (1), in particular a measuring transducer, with an encapsulating housing (2) and with at least one active component (3), which is arranged in the encapsulating housing (2). The at least one active component (3) is coated with at least one polymer (4). A method according to the invention for increasing the dielectric strength in a high-voltage device (1) involves at least one active component (3), which is arranged in an encapsulating housing (2), in particular filled with clean air (6), being coated with at least one polymer (4), in particular by shrink-fitting a shrink tube and/or by immersion-bath coating and/or by spray coating, wherein the polymer (4) is applied in particular as polytetrafluoroethylene (PTFE), polychlorotrifluoroethylene (PCTFE), polyolefin and/or an ethylenetetrafluoroethylene copolymer (ETFE).

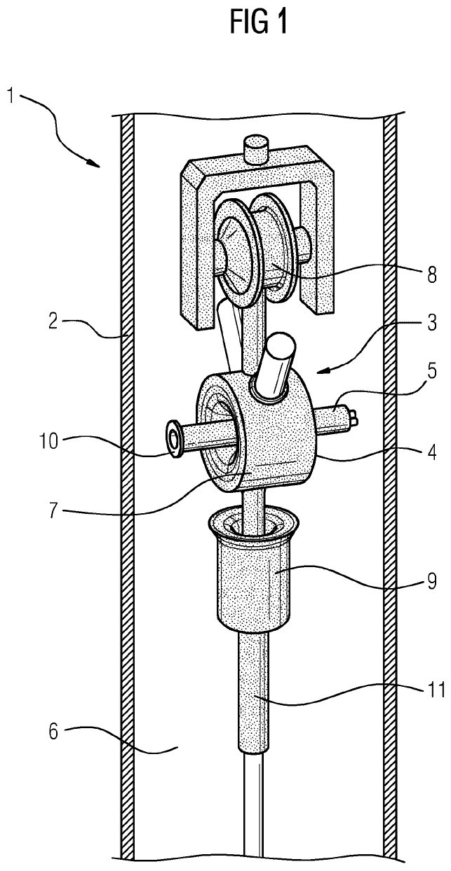

Coated active component in a high-voltage device, and method for increasing the dielectric strength

The invention relates to a high-voltage device, in particular a measuring transducer, comprising an encapsulating housing and comprising at least one active component, which is arranged in the encapsulating housing, and to a method for increasing the dielectric strength in a high-voltage device.

High-voltage devices, (e.g., measuring transducers), in particular current transducers, voltage transducers, and/or combination transducers, are known, e.g., from EP 0 236 974 B1. The measuring transducers are configured for measuring currents in the region of up to a few thousand amperes, and/or voltages of up to a few hundred kilovolts. Active components are arranged in a housing or encapsulation housing, which comprises e.g., an insulator, in particular a ribbed ceramic and/or silicone insulator. Active components are electrically conductive components which, in a measuring transducer, are surrounded during operation by an electric field. In order to prevent electric arcing among active components and/or between active components and the housing, the housing is configured to be gastight and is filled in the interior with an insulating gas, e.g., SF₆.

SF₆ is an insulating gas having good electrically insulating properties, but is harmful to the environment. SF₆ has a very high global warming potential, e.g., 23500 times higher than CO₂. Air, in particular pure, dry air, referred to in the following as clean air and/or synthetic air, is climate-neutral and therefore environmentally friendly. However, the electrically insulating properties of clean air are worse than those of SF₆. When SF₆ is used, high costs are associated with a gas-tight embodiment of high-voltage devices. When clean air is used, high costs are associated with a configuration of the high-voltage devices for very high pressures and/or large distances between active components and/or between active components and the housing.

The object of the present invention is that of specifying a high-voltage device and a method for increasing the dielectric strength in a high-voltage device, which solves the problems described above. In particular, the object is to specify a high-voltage device which allows for high voltage levels in a cost-effective and material-saving manner, in particular in the case of use of alternative insulating gases, such as clean air or synthetic air, at high dielectric strength, in particular when using insulating gases having low gas pressures, e.g., in the range of ambient air, and/or a compact design, in particular having dimensions of SF₆-filled devices.

The stated object is achieved according to the invention by a high-voltage device having the features according to claim 1, and/or by a method for increasing the dielectric strength in a high-voltage device, in particular a high-voltage device described above, according to claim 11. Advantageous embodiments of the high-voltage device according to the invention and/or of the method according to the invention for increasing the dielectric strength in a high-voltage device, in particular a high-voltage device describe above, are specified in the dependent claims. In this case, the features of the main claims can be combined with one another and with features of dependent claims, and features of the dependent claims can be combined with one another.

A high-voltage device according to the invention comprises an encapsulating housing and at least one active component, which is arranged in the encapsulating housing. The at least one active component is coated with at least one polymer.

The coating with the at least one polymer allows for electrical insulation of the at least one active component with respect to other components. As a result, electric arcing is prevented during operation of the high-voltage device or when a voltage is applied to active components, which arching can lead to damage or even destruction of components. Coating of active components with polymers is cost-effective, saves distances and thus material, wherein high voltage levels are made possible. The use of alternative insulating gases, such as clean air or synthetic air, is possible, in particular in compact structures, at high dielectric strength. Insulating gasses can be used at low gas pressures, e.g. in the range of ambient air, in a compact structure, in particular having dimensions of SF₆-filled devices, without electric arcing between active components leading to damage and/or destruction of components when high voltage is applied to the high-voltage device.

The at least one polymer can be formed on the at least one component in the form of an insulating layer. The insulating layer can have a layer thickness in the range of 0.5 to 5 millimetres and/or be in the region of one millimetre and above. In contrast to pure lacquer coating layers, which are applied very thinly onto components, thick polymer layers, in particular of the above-described thickness, have a good electrical insulating effect, such that damage and/or destruction of components when high voltage is applied to the high-voltage device is prevented.

The high-voltage device can comprise a measuring transducer and/or be a measuring transducer, in particular a current transducer, a voltage transducer and/or a combination transducer. In the case of measuring transducers, good electrical insulation, in particular when using insulating gases such as clean air or synthetic air, in compact structures and/or in the case of high voltages is important in order to exclude measuring errors and malfunctions.

The encapsulating housing can be filled in part or completely with clean air, in particular dry, purified air, in particular at a pressure in the range of from 7 to 15 bar. Clean air has a lower electrical insulation capacity compared e.g. with SF₆ as the insulating gas, as a result of which there is a risk of electric arching between in particular active components, with in particular the same dimensions of components of the high-voltage device. In this case, an insulation comprising at least one polymer effectively and at a low cost prevents electric arching between components, in particular when high voltage is applied to the high-voltage device, as a result of which damage, or even destruction, of components and/or of the high-voltage device is prevented.

The at least one active component can be and/or comprise a current and/or voltage active part, in particular a core shell of a current and/or voltage active component, an electrode, a conductor through which current flows, in particular a primary conductor, and/or a discharge pipe. In the case of the active components described above, there is a high risk of electric arcing, in particular in the case of applied high voltage, with the disadvantages described above, and therefore insulation with a polymer has a particularly advantageous effect.

The at least one polymer can be configured in the form of shrink tubing and/or in the form of dip coating, and/or in the form of a sprayed-on coating, and/or in the form of vulcanisation. Such methods of applying polymers onto active components, as electrical insulation, can be produced easily and cost-effectively, with a high insulation or protection effect.

The at least one polymer can be and/or comprise polytetrafluoroethylene (PTFE), polychlorotrifluoroethylene (PCTFE), polyolefin, and/or ethylene tetrafluoroethylene copolymer (ETFE), and/or mixtures of these substances. The above-mentioned materials exhibit high mechanical stability and a high electrical insulating effect, can be easily processed and/or applied as a layer, are long-term stable, and are cost-effective. Thus, such materials are well suited as polymers for coating active components, with the advantages described above.

The at least one active component, in particular a core shell of a current and/or voltage active component and/or a discharge pipe, can be coated in part, in particular on the outside, with the at least one polymer. Partial coating makes it possible for material to be saved in regions where electric arcing is unlikely, and/or regions for electrical contacting can be saved from the coating. An outer coating be sufficient in order to prevent electric arching between active components.

The at least one active component, in particular an electrode and/or a primary conductor, can be fully coated with the at least one polymer. In the case of components such as electrodes and/or primary conductors, risks of electric arcing can exist over their entire length or width, due to an applied voltage, in particular high voltage, as a result of which a full coating may be necessary in order to reliably prevent electric arching over said active components, with the advantages described above.

A method according to the invention for increasing the dielectric strength in a high-voltage device, in particular in a high-voltage device described above, includes at least one active component, which is arranged in an encapsulating housing, in particular filled with clean air, is coated with at least one polymer, in particular by shrinking on shrink tubing and/or by dip coating and/or by spray coating and/or by vulcanisation, wherein the polymer is in particular applied as polytetrafluoroethylene (PTFE), polychlorotrifluoroethylene (PCTFE), polyolefin, and/or ethylene tetrafluoroethylene copolymer (ETFE).

The advantages of the method according to the invention for increasing the dielectric strength in a high-voltage device, in particular in a high-voltage device described above according to claim 11, are analogous to the above-described advantages of the high-voltage device according to the invention according to claim 1, and vice versa.

An embodiment of the invention will be shown schematically in the following in the one FIGURE, and will be described in more detail below.

In this case, the

[symbol]

[symbol] FIGURE is a schematic sectional view of a detail of a high-voltage device 1 according to the invention, comprising active components 3, 7, 8, 9, 10, 11 which are coated with insulating layers 5 made of polymer 4.

The one FIGURE is a sectional view of a detail of a high-voltage device 1 according to the invention. The high-voltage device 1 comprises active components 3, in particular a current active part 7, a voltage active part S, a control electrode 9, a primary conductor 10, and/or a discharge pipe 11. The active components 3 are each coated with an insulating layer 5 made of at least one polymer 4.

The high-voltage device 1 is e.g., a measuring transducer, in particular a current transducer, a voltage transducer, and/or a combination transducer. Thus, e.g., measurements of voltages in the range of up to a few hundred kilovolts, i.e. high voltages, and/or of currents in the range of up to a few thousand amperes, are possible. The high-voltage device 1 comprises an encapsulating housing 2, in the interior of which the active components 3, in particular a current active part 7, a voltage active part 8, a control electrode 9, a primary conductor 10, and/or a discharge pipe 11 are arranged. The encapsulating housing 2 of the high-voltage device 1 is e.g., configured as an insulator, in particular as an externally ribbed, ceramic, silicone and/or composite material insulator. Alternatively or in addition, the encapsulating housing 2 is configured in the shape of a caldron, e.g., as a metal caldron.

The encapsulating housing 2 is configured to be gas-tight, and e.g., is filled with clean air as the insulating gas, i.e. purified, dry air. Alternatively, insulating gases such as SF₆ or gas mixtures can be used. The pressure of the insulating gas is e.g. equal to the ambient pressure, i.e., 1 bar, or up to 6 bar, in particular in the case of use of SF₆, or e.g., in the range of 7 to 15 bar, in particular in the case of use of clean air. The use of encapsulating housings 2 filled with clean air, having dimensions of conventional encapsulating housings 2 of SF₆ high-voltage devices 1, saves material and costs. Clean air has worse electrical insulating properties than SF₆. In order to reliably prevent electric arcing between components, in particular active components 3 and/or the encapsulating housing 2, e.g., in the case of clean air as the insulating gas in encapsulating housings 2 having dimensions of SF₆ high-voltage devices 1, according to the invention the active components 3 are covered or coated with an insulating layer 5 made of polymer 4.

The polymer 4 of the insulating layer 5 is e.g. polytetrafluoroethylene (PTFE), polychlorotrifluoroethylene (PCTFE), one or more polyolefins, and/or ethylene tetrafluoroethylene copolymer (ETFE), or comprises polytetrafluoroethylene (PTFE), polychlorotrifluoroethylene (PCTFE), polyolefins, and/or ethylene tetrafluoroethylene copolymers (ETFE). These materials exhibit good electrically insulating properties. Further materials are e.g., other plastics materials. The insulating layer 5 is configured to have a layer thickness in the range of 0.5 to 5 millimetres and/or in the region of one millimetre and above. In contrast to thin lacquer insulations, thick layers are capable of ensuring sufficient electrical insulation of the active components 3, in particular in a long-term stable manner, at high voltages. The insulating layer 5 is e.g., configured in the form of shrink tubing and/or in the form of dip coating, and/or in the form of vulcanisation. Such coatings can be produced easily and cost-effectively.

As shown in the embodiment of the one figure, an active component 3, e.g., a core shell or a current and/or voltage active part 7, 8, and/or a discharge pipe 11, is coated in part on the outside with the insulating layer 5. An outer, in particular partial, coating is sufficient for reliably preventing electric arcing between the active components 3. In regions without a coating, contacting can take place and/or there is sufficient distance from other active components 3 in order to prevent electric arcing. An electrode 9 and/or a conductor through which current flows, in particular a primary conductor 10, are e.g., fully coated, in order to achieve sufficient insulation with respect to other active components 3. The above-described coatings are merely examples, and can also be performed specifically, coated fully and/or coated only in part, in particular with different layer thicknesses, depending on the structure of the high-voltage device 1.

The embodiment described above can be combined with the prior art. Thus e.g. high-voltage devices 1 can include high-voltage power circuit breakers, cutoff switches, transformers, surge arresters, measuring transducers, and/or grommets. The invention can be used in dead tank systems, i.e., having an earthed housing, or in live tank systems, i.e., having electric units at high-voltage potential, arranged in an insulator.

Insulating layers 5 made of polymer 4 are e.g., configured as a layer or as a layer stack of a plurality of layers. In this case, the layers can have different permittivity, in particular decreasing permittivity from layer to layer. The application of further insulating layers of different relative permittivity, wherein e.g., the permittivity of the inner layer is the highest, and each further layer is configured having a lower or having reducing permittivity, but always having a permittivity greater than the permittivity of gas, i.e. greater than 1, makes it possible for a more pronounced homogenisation of the electric field to be achieved compared with just one layer, in order to thus further dielectrically relieve the critical regions.

### LIST OF REFERENCE NUMERALS

high-voltage device
encapsulating housing
active component
polymer
insulating layer
clean air
current active part
voltage active part
electrode, e.g. control electrode
conductor through which current flows, e.g. primary conductor
discharge pipe
PTFE polytetrafluoroethylene
PCTFE polychlorotrifluoroethylene
ETFE ethylene tetrafluoroethylene copolymer

1. A high-voltage device, comprising an encapsulating housing and at least one active component-arranged in the encapsulating housing, wherein the at least one active component is coated with at least one polymer.

2. The high-voltage device according to claim 1, wherein the at least one polymer is formed on the at least one active component in the form of an insulating layer.

3. The high-voltage device according to claim 1, wherein the insulating layer has a layer thickness in a range of 0.5 to 5 millimetres or in a region of one millimetre and above.

4. The high-voltage device according to claim 1, wherein the high-voltage device includes a measuring transducer or is a measuring transducer.

5. The high-voltage device according to claim 1, wherein the encapsulating housing is filled in part or completely with clean air.

6. The high-voltage device according to claim 1, wherein the at least one active component is any combination of a current active part and a voltage active part or includes any combination of a current active part and a voltage active part.

7. The high-voltage device according to claim 1, wherein the at least one polymer is configured in the form of any combination of a shrink tubing, a dip coating, a spray coating, and vulcanization.

8. The high-voltage device according to claim 1, wherein the at least one polymer comprised of any combination of polytetrafluoroethylene (PTFE), polychlorotrifluoroethylene (PCTFE), polyolefin, and ethylene tetrafluoroethylene copolymers (ETFE).

9. The high-voltage device according to claim 1, wherein the at least one active component is comprised of a core shell.

10. The high-voltage device according to claim 1, wherein the at least one active component is comprised of any combination of an electrode and a primary conductor.

11. A method for increasing a dielectric strength in a high-voltage device, the method comprising:
providing an encapsulating housing;
providing at least one active component arranged in the encapsulating housing; and
coating the at least one active component with at least one polymer, wherein the encapsulating housing is filled with clean air.

12. The high-voltage device according to claim 1, wherein the high-voltage device is any combination of a current transducer, a voltage transducer and a combination transducer.

13. The high-voltage device according to claim 5, wherein the clean air is dry, purified air.

14. The high-voltage device of claim 5, wherein the clean air is at a pressure in a range of 7 to 15 bar.

15. The high-voltage device according to claim 1, wherein the at least one active component is comprised of a core shell that further comprises any combination of a current active part, a voltage active part, an electrode, and a conductor through which current flows.

16. The high-voltage device according to claim 1, wherein the conductor further comprises any combination of a primary conductor and a discharge pipe.

17. The high voltage device according to claim 9, wherein the core shell is comprised of any combination of a current active part, a voltage active part and a discharge pipe, and wherein the core shell is coated in part with the at least one polymer.

18. The high-voltage device according to claim 17, wherein the polymer coating is on the outside of the core shell.

19. The method of claim 11, wherein the at least one polymer is applied by any combination of shrink tubing, dip coating, spray coating, and vulcanization.
